(19) United States
(12) Patent Application Publication
(10) Pub. No.: US 2014/0060895 A1
(43) Pub. Date: Mar. 6, 2014

(54) CLIP ASSEMBLY AND HEAT DISSIPATION DEVICE INCORPORATING THE SAME

(71) Applicants: CHAMP TECH OPTICAL (FOSHAN) CORPORATION, Foshan (CN); FOXCONN TECHNOLOGY CO., LTD., New Taipei (TW)

(72) Inventors: MING-WEI CHEN, Foshan (CN); JING ZHANG, Foshan (CN); TAO LI, Foshan (CN)

(73) Assignees: FOXCONN TECHNOLOGY CO., LTD., New Taipei (TW); CHAMP TECH OPTICAL (FOSHAN) CORPORATION, Foshan (CN)

(21) Appl. No.: 13/726,545

(22) Filed: Dec. 25, 2012

(30) Foreign Application Priority Data
Aug. 31, 2012 (CN) 2012103174665

(51) Int. Cl. F16B 2/24; H05K 1/02

(52) U.S. Cl. CPC F16B 2/248; H05K 1/0203
USPC 174/252; 24/462

(57) ABSTRACT

An exemplary heat dissipation device includes a heat sink and a clip assembly spanning the heat sink. The clip assembly includes a wire clip and two fasteners engaging with the wire clip. The wire clip includes a main body and two engaging arms extending outwardly from two ends of the main body respectively. Each engaging arm includes a first section extending outwardly from the main body, a second section opposite to the first section, an engaging portion interconnecting the first section with the second section, and a hook bent outwardly from a free end of the second section. The main body and the hook of each engaging arm are hooked on the heat sink, and each fastener extends through the corresponding engaging portion. The engaging portions are resiliently pressed by the fasteners, and the heat sink is pressed downwardly by the main body of the wire clip.

### BACKGROUND

1. Technical Field

The present disclosure relates to heat dissipation apparatuses, and more particular to a clip assembly and a heat dissipation device incorporating the clip assembly.

2. Description of Related Art

With advancements in computer technology, many electronic devices such as central processing units and chips operate at a high speed nowadays. It is well known that the more rapidly the electronic devices operate, the more heat they generate. If the heat is not timely dissipated, the stability of operation of the electronic devices may be impacted severely. Generally, in order to ensure that the electronic device runs normally, a heat dissipation device is used to dissipate the heat generated by the electronic device.

Typically, the heat dissipation device includes a heat sink and a clip assembly. The clip assembly facilitates close attachment of the heat sink onto an electronic device, so that the heat sink can efficiently dissipate heat generated by the electronic device. The clip assembly usually has a wire clip, which is integrally made of a resilient metal wire. The clip abuts against the heat sink, with two ends of the clip locked on a printed circuit board on which the electronic device is mounted, thereby providing pressure for securing the heat sink on the electronic device. However, the amount of pressure directly exerted downwardly against the heat sink by the clip is difficult to control. When the fastening force is too small, the heat-dissipation efficiency is usually low because of loose attachment of the heat sink onto the electronic device. Conversely, when the fastening force is too large, it may damage the electronic device.

What is needed, therefore, is an improved clip assembly and a heat dissipation device incorporating the clip assembly which can overcome the above described shortcomings.

### BRIEF DESCRIPTION OF THE DRAWINGS

FIG. 1 is an isometric, exploded view of a heat dissipation device according to an exemplary embodiment of the present disclosure.

FIG. 2 is an assembled view of the heat dissipation device of FIG. 1.

FIG. 3 is a schematic, side view of the heat dissipation device of FIG. 2 mounted on a printed circuit board.

### DETAILED DESCRIPTION

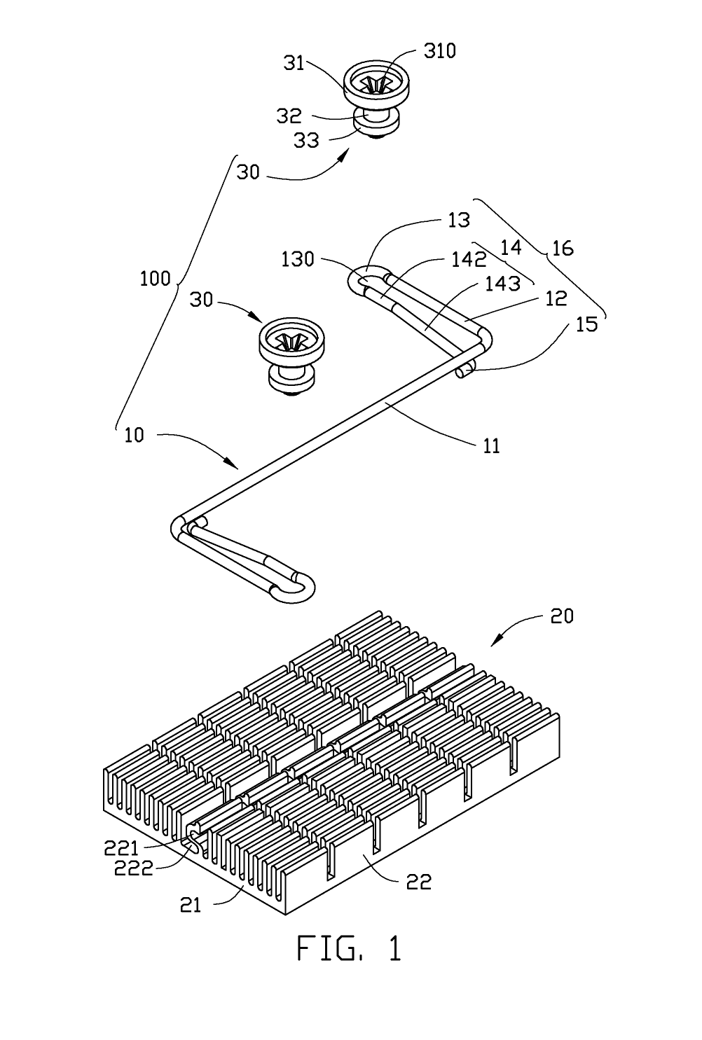

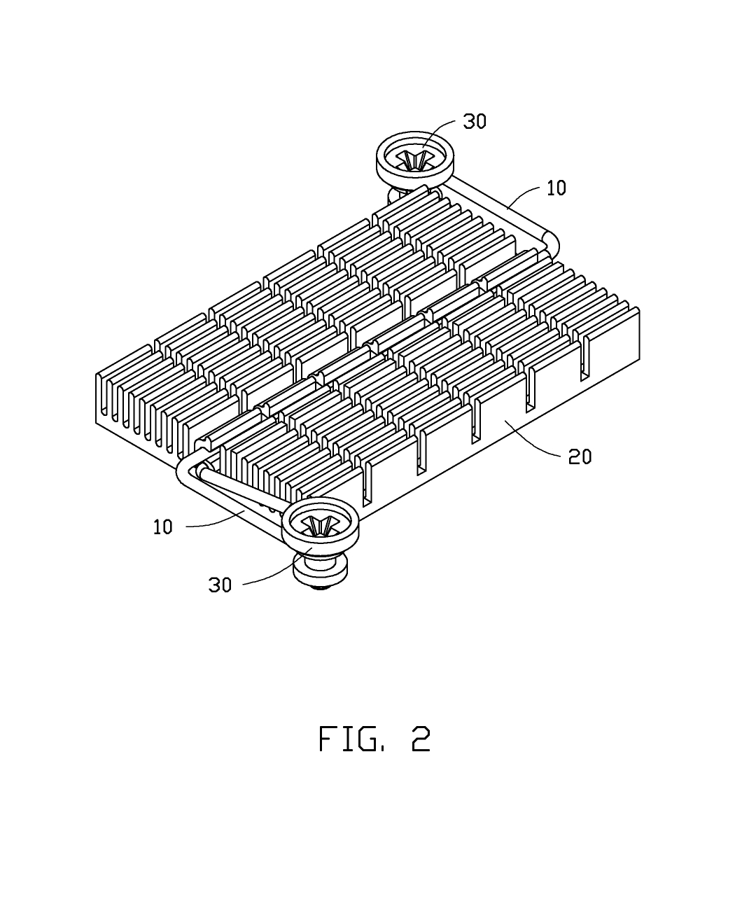

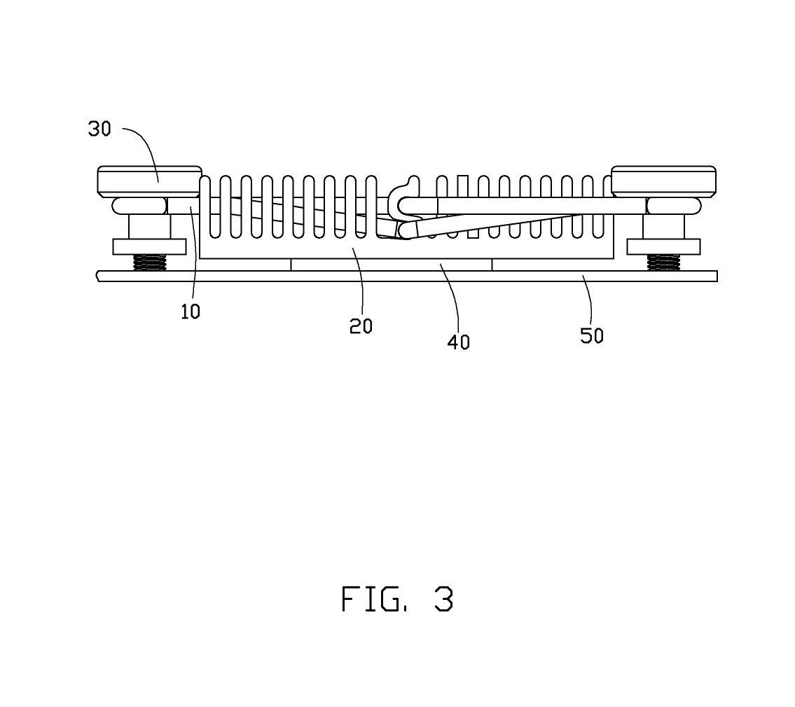

Referring to FIGS. 1 through 3, a heat dissipation device according to an exemplary embodiment comprises a heat sink 20 and a clip assembly 100 spanning the heat sink 20.

The clip assembly 100 comprises a wire clip 10 and two fasteners 30 engaging with the wire clip 10. The wire clip 10 is integrally made of a single monolithic piece of resilient metal wire. The wire clip 10 comprises a main body 11, and two engaging arms 16 extending outwardly from two ends of the main body 11, respectively. In the present embodiment, the two engaging arms 16 extend along two substantially opposite directions, respectively. Each engaging arm 16 comprises a first section 12 extending perpendicularly from the main body 11, a second section 14 opposite to the first section 12, an engaging portion 13 interconnecting the first section 12 with the second section 14, and a hook 15 bent outwardly from a free end of the second section 14. The engaging portion 13 is curved and defines a through opening 130. In the illustrated embodiment, the engaging portion 13 is U-shaped and defines the through opening 130 in the hollow of the U-shape. The second section 14 comprises a first portion 142 extending outwardly from the engaging portion 13, and a second portion 143 bent slightly downwardly from the first portion 142. The first portion 142 of the second section 14 is parallel to the first section 12, and the first portion 142 is coplanar with the main body 11, the first section 12 and the engaging portion 13. The hook 15 of each engaging arm 16 is located under the main body 11, and the hook 15 is parallel with the main body 11. The two hooks 15 extend towards each other.

The heat sink 20 is integrally made of a material having a good heat conductivity coefficient, such as copper, aluminum, or an alloy thereof. The heat sink 20 comprises a base plate 21, and a plurality of fins 22 protruded upwardly from a top face of the base plate 21. The base plate 21 is a rectangular plate with a uniform thickness. A center of a bottom of the base plate 21 is used to thermally contact an electronic component 40 which is mounted on a printed circuit board 50. Each fin 22 is an elongated strip perpendicular to the top face of the base plate 21, except for a single line of the fins 22 along a center of the base plate 21. The fins 22 are all spaced from each other, and all the fins 22 except the center line of the fins 22 are parallel to each other. The base plate 21 transfers heat to the fins 22, and the fins 22 dissipate the heat by natural air convection and thermal radiation.

The plurality of fins 22 define a first receiving slot 221 and a second receiving slot 222 for accommodating the wire clip 10 of the clip assembly 100. The first receiving slot 221 and the second receiving slot 222 extend lengthways (perpendicularly) through the plurality of fins 22. The first receiving slot 221 and the second receiving slot 222 are defined at a center of the plurality of fins 22. The first receiving slot 221 is located directly above the second receiving slot 222. Both the first receiving slot 221 and the second receiving slot 222 are defined by the center line of the fins 22. The fins 22 of the center line of the fins 22 are aligned with each other. Each fin 22 of the center line of the fins 22 has a bent profile, such that when the fin 22 is viewed in conjunction with the corresponding portion of the top face of the base plate 21, the fin 22 and the base plate 21 cooperatively form an approximately S-shaped configuration. The first receiving slot 221 corresponds to the upper hollow in the S-shape, and the second receiving slot 222 corresponds to the lower hollow in the S-shape. Thus the first receiving slot 221 can be considered to face (or be open towards) a first direction (toward a right side of the heat sink 20), and the second receiving slot 222 can be considered to face (or be open towards) a second direction (toward a left side of the heat sink 20) opposite to the first direction.

The main body 11 of the wire clip 10 is snugly received in the first receiving slot 221 of the heat sink 20. The two hooks 15 of the wire clip 10 are respectively inserted into and received in the second receiving slot 222. Because the direction in which the first receiving slot 221 faces is contrary to the direction in which the second receiving slot 222 faces, the main body 11 and the hooks 15 prevent movement of the wire clip 10 relative to the heat sink 20.

Each of the fasteners 30 comprises a cap-shaped head 31, a cylindrical post 32 extending coaxially downwardly from a bottom of the head 31, and an annular protrusion (ring) 33 protruding outwardly from an outer circumference of the post 32. A crisscross groove 310 is defined in a top face of the head 31, and is adapted for facilitating a tool to operate the fastener 30. An outer periphery of a bottom end of the post 32 is threaded for screwing into the printed circuit board 50. A diameter of the post 32 is smaller than that of the head 31. The protrusion 33 is spaced from the head 31 and located at about a middle of the post 32.

In assembly of the heat dissipation device, each fastener 30 is extended into the through opening 130 of the engaging portion 13 of a corresponding engaging arm 16 of the wire clip 10. The post 32 of the fastener 30 is partially encircled by the engaging portion 13, and the engaging portion 13 is sandwiched between the head 31 and the annular protrusion 33 of the fastener 30. A downward pressure is exerted on the fastener 30 by, e.g., a human operator, to make the post 32 extend towards the printed circuit board 50, and then the post 32 is screwed into the printed circuit board 50. The engaging portion 13 is pressed downwardly by the head 31 of the fastener 30. Thus the engaging portions 13 of the wire clip 10 are resiliently pressed by the fasteners 30, and a resilient deformation of at least the engaging arms 16 of the wire clip 10 causes the main body 11 to press downwardly towards the base plate 21 of the heat sink 20. Thereby, the heat sink 20 and the printed circuit board 50 are finally secured together by the clip assembly 100, and the base plate 21 is tightly attached on the electronic component 40.

Additionally, the main body 11 and the hooks 15 of the wire clip 10 are both fixed on the heat sink 20. The more the head 31 of the fastener 30 presses downwardly on the engaging portion 13, the more the wire clip 10 resiliently deforms, and the greater the amount of the force exerted on the heat sink 20. Thus, an appropriate force exerted by the clip assembly 100 on the heat sink 20 can be easily obtained by controlling the depth that the fasteners 30 are screwed into the printed circuit board 50.

It is to be further understood that even though numerous characteristics and advantages of the present embodiments have been set forth in the foregoing description, together with details of the structures and functions of the embodiments, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. A heat dissipation device for dissipating heat generated by an electronic component mounted on a printed circuit board, the heat dissipation device comprising:
a heat sink; and
a clip assembly spanning the heat sink and securing the heat sink on the printed circuit board, the clip assembly comprising a wire clip and two fasteners engaging with the wire clip, the wire clip comprising a main body and two engaging arms extending outwardly from two ends of the main body, respectively, each engaging arm comprising a first section extending outwardly from the main body, a second section opposite to the first section, an engaging portion interconnecting the first section with the second section, and a hook bent outwardly from a free end of the second section;
wherein the main body and the hook of each engaging arm of the wire clip are hooked on the heat sink, and each fastener extends through the engaging portion of a corresponding engaging arm and is screwed into the printed circuit board, the engaging portions of the wire clip are resiliently pressed by the fasteners, and the heat sink is pressed downwardly by the main body of the wire clip.

2. The heat dissipation device of claim 1, wherein the heat sink comprises a base plate and a plurality of fins protruding upwardly from the base plate.

3. The heat dissipation device of claim 2, wherein the fins define a first receiving slot for accommodating the main body of the wire clip and a second receiving slot for accommodating the hooks of the wire clip.

4. The heat dissipation device of claim 3, wherein the first receiving slot and the second receiving slot extend lengthways through the plurality of fins.

5. The heat dissipation device of claim 3, wherein the first receiving slot is located above the second receiving slot.

6. The heat dissipation device of claim 3, wherein the direction in which a long opening of the first receiving slot faces is contrary to the direction in which a long opening of the second receiving slot faces.

7. The heat dissipation device of claim 1, wherein the engaging portion of each engaging arm is curved and defines a through opening for the corresponding fastener to extend through.

8. The heat dissipation device of claim 1, wherein the two engaging arms extend along two substantially opposite directions, respectively.

9. The heat dissipation device of claim 1, wherein the main body is coplanar with the first section and the engaging portion of each engaging arm.

10. The heat dissipation device of claim 1, wherein the second section comprises a first portion extending outwardly from the engaging portion, and a second portion bent downwardly from the first portion.

11. A clip assembly comprising:
a wire clip comprising a main body and two engaging arms extending outwardly from two ends of the main body, respectively, each engaging arm comprising a first section extending outwardly from the main body, a second section opposite to the first section, an engaging portion interconnecting the first section with the second section, and a hook bent outwardly from a free end of the second section; and
two fasteners for engaging with the two engaging portions of the wire clip, respectively, wherein when the fasteners press down on the engaging portions and the main body remains in a fixed position the engaging arms resiliently deform.

12. The clip assembly of claim 11, wherein the engaging portion of each engaging arm is curved and defines a through opening for the corresponding fastener extending through.

13. The clip assembly of claim 11, wherein the two engaging arms extend along two substantially opposite directions, respectively.

14. The clip assembly of claim 11, wherein the main body is coplanar with the first section and the engaging portion of each engaging arm.

15. The clip assembly of claim 11, wherein the second section comprises a first portion extending outwardly from the engaging portion, and a second portion bent downwardly from the first portion.

16. The clip assembly of claim 11, wherein the two hooks extend towards each other.

17. The clip assembly of claim 11, wherein the wire clip is integrally made of a single monolithic piece of resilient metal wire.

18. A heat dissipation device comprising:
a heat sink comprising a base plate and a plurality of fins protruding upwardly from the base plate; and
a clip assembly spanning the heat sink, the clip assembly comprising a wire clip and two fasteners engaging with the wire clip, the wire clip comprising a main body and two engaging arms extending outwardly from two ends of the main body, respectively, each engaging arm comprising a first section extending outwardly from the main body, a second section opposite to the first section, an engaging portion interconnecting the first section with the second section, and a hook bent outwardly from a free end of the second section;
wherein the main body and the hook of each engaging arm of the wire clip are hooked on the heat sink, and each fastener is configured to extend through the engaging portion of a corresponding engaging arm and be fixed to a printed circuit board such that the engaging portions of the wire clip are resiliently pressed by the fasteners and the heat sink is pressed downwardly by the main body of the wire clip.

19. The heat dissipation device of claim 18, wherein the plurality of fins define a first receiving slot in which the main body of the wire clip is hooked and a second receiving slot in which the hooks of the wire clip are hooked.

20. The heat dissipation device of claim 19, wherein the fins of a center line of the plurality of fins are aligned with each other, each fin of the center line has a bent profile, such that when the fin is viewed in conjunction with a corresponding portion of the base plate, the fin and the base plate cooperatively form an approximately S-shaped configuration, the first receiving slot corresponds to the upper hollow of the S-shaped configuration, and the second receiving slot corresponds to the lower hollow of the S-shaped configuration.
